(19) United States
(12) Patent Application Publication
(10) Pub. No.: US 2025/0318252 A1
(43) Pub. Date: Oct. 9, 2025

(54) Power Semiconductor Device and Method of Producing a Power Semiconductor Device

(71) Applicant: Infineon Technologies Austria AG, Villach (AT)

(72) Inventors: Erich Griebl, Dorfen (DE); Jana Hänsel, Dresden (DE)

(21) Appl. No.: 19/173,287

(22) Filed: Apr. 8, 2025

(30) Foreign Application Priority Data
Apr. 9, 2024 (DE) 102024203240.9

(51) Int. Cl. H10D 84/00; H10D 12/00; H10D 30/66; H10D 62/10; H10D 84/01; H10D 89/60

(52) U.S. Cl. CPC H10D 84/148; H10D 12/481; H10D 30/665; H10D 30/668; H10D 62/103; H10D 84/0109; H10D 89/611

(57) ABSTRACT

A power semiconductor device includes: a semiconductor body configured to conduct a forward load current between first and second load terminals; a main control terminal; an auxiliary control terminal isolated from the main control terminal; a control electrode structure including: main control electrodes electrically connected to the main control terminal and configured to control the forward load current, and auxiliary control electrodes electrically connected to the auxiliary control terminal and configured to control an overload current; and an overload structure electrically connected between the second load terminal and the auxiliary control terminal, the overload structure configured to apply an auxiliary control voltage greater than a threshold voltage to the auxiliary control trench electrodes, if a voltage between the first and second load terminals exceeds a maximal value and/or if the voltage between the second load terminal and the auxiliary control terminal is above a breakthrough voltage of the overload structure.

### TECHNICAL FIELD

This specification refers to embodiments of a power semiconductor device and to embodiments of a method of producing a power semiconductor device. The power semiconductor device may exhibit a voltage self-clamping configuration.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device. The load current is conducted by means of an active region of the power semiconductor device. The active region is surrounded by an edge termination region, which is terminated by an edge of the chip.

In case of a controllable power semiconductor device, e.g., a transistor, the load current path may be controlled by means of insulated electrodes, commonly referred to as gate electrodes. For example, upon receiving a corresponding control signal, e.g., from a driver unit and via a control terminal of the device, the control electrodes may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

In a typical IGBT design, the gate electrodes are accommodated in a trench structure that extends into the semiconductor body. The trench structure spatially confines portions of the semiconductor body, typically referred to as mesas, in which conductive channels may be formed that allow flow of the forward load current. The conductive channels, typically based on a semiconductor source region and a semiconductor body region of opposite conductivity type as the source region, are controlled based on the adjacent control electrodes.

Even when turned-off, an overvoltage can force a current through the device. For example, such current is forced by an inductor, by a lighting discharge or the like. Some devices are configured to deal with such situation at least for a certain amount of time or a certain dissipated energy without getting destroyed. Such a device is commonly referred to as “voltage self-clamping device” or as “avalanche rugged device”.

Two modes of self-clamping can be distinguished from each other: one mode is known as “power clamping”, in which the device remains turned-off and the heat produced by the forced current through the device is dissipated via the active area. The other mode is known as “active clamping”, in which, when detecting the overvoltage, the device is turned-on by subjecting the gate electrode with a corresponding control signal.

The present disclosure is related to the “active clamping” mode.

### SUMMARY

The subject-matter of the independent claims is presented. Features of exemplary embodiments are defined in the dependent claims.

According to an embodiment, a power semiconductor device comprises: an active region surrounded by an edge termination region; a semiconductor body extending in both the active region and the edge termination region and comprising, in the active region a semiconductor drift region of a first conductivity type; a first load terminal at a first side of the semiconductor body; a second load terminal at a second side of the semiconductor body opposite to the first side, wherein the power semiconductor device is configured to conduct, in the active region a forward load current between the first load terminal and the second load terminal; a main control terminal; an auxiliary control terminal isolated from the main control terminal; in the active region, a trench structure extending along a vertical direction from the first side towards the second side, wherein the trench structure comprises main control trenches, each of the main control trenches including a main control trench electrode electrically connected to the main control terminal and configured to control the forward load current, and auxiliary control trenches, each of the auxiliary control trenches including an auxiliary control trench electrode electrically connected to the auxiliary control terminal and configured to control an overload current; an overload structure connected between the second load terminal and the auxiliary control terminal, wherein the overload structure is configured to apply an auxiliary control voltage greater than a threshold voltage to the auxiliary control trench electrodes, if a voltage between the first load terminal and the second load terminal exceeds a maximal value and/or if the voltage between the second load terminal and the auxiliary control terminal is above a breakthrough voltage of the overload structure.

According to a further embodiment, a power semiconductor device comprises: a semiconductor body; a first load terminal; a second load terminal, wherein the power semiconductor device is configured to conduct a forward load current between the first load terminal and the second load terminal; a main control terminal; an auxiliary control terminal isolated from the main control terminal; a control electrode structure comprising: main control electrodes electrically connected to the main control terminal and configured to control the forward load current, and auxiliary control electrodes electrically connected to the auxiliary control terminal and configured to control an overload current; an overload structure electrically connected between the second load terminal and the auxiliary control terminal, wherein the overload structure is configured to apply an auxiliary control voltage greater than a threshold voltage to the auxiliary control electrodes, if a voltage between the first load terminal and the second load terminal exceeds a maximal value and/or if the voltage between the second load terminal and the auxiliary control terminal is above a breakthrough voltage of the overload structure.

According to another embodiment, a method of producing a power semiconductor device comprises forming the following components: an active region surrounded by an edge termination region; a semiconductor body extending in both the active region and the edge termination region and comprising, in the active region a semiconductor drift region of a first conductivity type; a first load terminal at a first side of the semiconductor body; a second load terminal at a second side of the semiconductor body opposite to the first side, wherein the power semiconductor device is configured to conduct, in the active region a forward load current between the first load terminal and the second load terminal; a main control terminal; an auxiliary control terminal isolated from the main control terminal; in the active region, a trench structure extending along a vertical direction from the first side towards the second side, wherein the trench structure comprises main control trenches, each of the main control trenches including a main control trench electrode electrically connected to the main control terminal and configured to control the forward load current, and auxiliary control trenches, each of the auxiliary control trenches including an auxiliary control trench electrode electrically connected to the auxiliary control terminal and configured to control an overload current; an overload structure connected between the second load terminal and the auxiliary control terminal, wherein the overload structure is configured to apply an auxiliary control voltage greater than a threshold voltage to the auxiliary control trench electrodes, if a voltage between the first load terminal and the second load terminal exceeds a maximal value and/or if the voltage between the second load terminal and the auxiliary control terminal is above a breakthrough voltage of the overload structure.

According to a yet further embodiment, a method of producing a power semiconductor device comprises forming the following components: a semiconductor body; a first load terminal; a second load terminal, wherein the power semiconductor device is configured to conduct a forward load current between the first load terminal and the second load terminal; a main control terminal; an auxiliary control terminal isolated from the main control terminal; a control electrode structure comprising: main control electrodes electrically connected to the main control terminal and configured to control the forward load current, and auxiliary control electrodes electrically connected to the auxiliary control terminal and configured to control an overload current; an overload structure electrically connected between the second load terminal and the auxiliary control terminal, wherein the overload structure is configured to apply an auxiliary control voltage greater than a threshold voltage to the auxiliary control electrodes, if a voltage between the first load terminal and the second load terminal exceeds a maximal value and/or if the voltage between the second load terminal and the auxiliary control terminal is above a breakthrough voltage of the overload structure.

In accordance with embodiments described herein, to actively turn-on the device in case of an overload situation, auxiliary electrodes are provided separately from the regular control electrodes employed for controlling the load current under nominal conditions. To supply the auxiliary control electrodes with a separate control signal, a correspondingly configured overload structure can be coupled to the auxiliary control electrodes. The separately provided auxiliary control electrodes may be integrated with the active region, e.g., as part of a mesa-trench-pattern. The control of the auxiliary control electrodes may occur independently of the control of the main control electrodes. That is, the auxiliary control electrodes may be electrically isolated from each other and provided with separate control signals.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a horizontal projection of a power semiconductor device in accordance with one or more embodiments;

FIG. 2 schematically and exemplarily illustrates a vertical cross-section of a power semiconductor device in accordance with one or more embodiments;

FIG. 3 schematically and exemplarily illustrates a circuit diagram of a power semiconductor device in accordance with an example;

FIG. 4 schematically and exemplarily illustrates a circuit diagram of a power semiconductor device in accordance with one or more embodiments;

FIGS. 5(A) and 5(B) schematically and exemplarily illustrate a horizontal projection of a power semiconductor device in accordance with one or more embodiments;

FIG. 6 schematically and exemplarily illustrates four views of sections of a power semiconductor device in accordance with one or more embodiments;

FIG. 7 schematically and exemplarily illustrates four views of sections of some embodiments of a power semiconductor device;

FIG. 8 schematically and exemplarily illustrates a horizontal projection of two variants of an overload structure of a power semiconductor device in accordance with one or more embodiments;

FIG. 9 schematically and exemplarily illustrates a horizontal projection of a power semiconductor device in accordance with one or more embodiments;

FIG. 10 schematically and exemplarily illustrates a section of a vertical cross-section of a power semiconductor device in accordance with one or more embodiments;

FIG. 11 schematically and exemplarily illustrates a horizontal projection of a power semiconductor device in accordance with one or more embodiments; and

FIG. 12 schematically and exemplarily illustrates a horizontal projection of a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, a potential of the control electrode. The electrical characteristics may, of course, only apply within a predetermined working range of the external voltage and the current density within the power semiconductor device. The term “forward biased blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 600V or even more, e.g., up to at least 1.2 kV, or even up to 6 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip, e.g., exhibiting a stripe cell configuration (or a cellular/needle cell configuration) and can be configured to be employed as a power component in a low-, medium- and/or high voltage application.

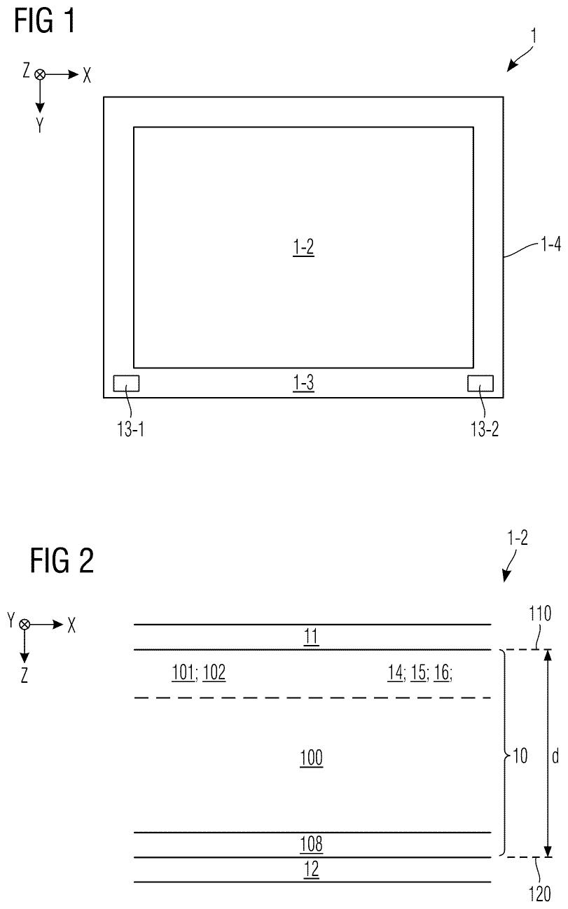

With respect to FIGS. 1 and 2, aspects related to a possible general configuration of the power semiconductor device 1 shall be explained:

The power semiconductor device 1, herein also referred to as “device 1”, comprises, e.g., in a single chip, a semiconductor body 10 configured to conduct, in an active region 1-2, a load current between a first load terminal 11 at a first side 110 of the semiconductor body 10 and a second load terminal 12 at a second side 120 of the semiconductor body 10. The device 1 can be, e.g., an IGBT (or a derivative thereof, such as RC IGBT) or, e.g., a MOSFET (or a derivative thereof). Accordingly, the first load terminal 11 may be an emitter terminal (or source terminal), and the second load terminal 12 may be a collector terminal (or drain terminal).

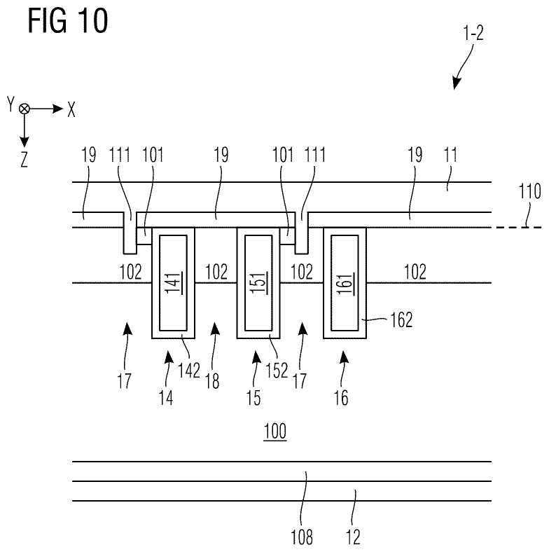

As exemplarily illustrated in FIG. 1, the active region 1-2 of the device 1 is surrounded by an edge termination region 1-3. In the active region 1-2, a trench structure (cf. also FIG. 10, reference numerals 14, 15, 16) may form a cell field, which will be explained further below. The edge termination region 1-3 is typically not employed for load current conduction, as it is known to the skilled person. The edge termination region 1-3 is terminated by the chip edge 1-4.

As exemplarily illustrated in FIG. 2, the first side 110 and the second side 120 may be arranged opposite of each other. For example, the first side 110 is a front side of the device 1 and the second side 120 is a back side of the device 1. Accordingly, the device 1 may exhibit a vertical configuration according to which the load current within the device 1 follows a path in parallel to the vertical direction Z. The semiconductor body 10 may be sandwiched between the first load terminal 11 and the second load terminal 12 and exhibit a vertical extension d, e.g., in the range of 40 μm to 500 μm, depending, e.g., on the maximal blocking voltage the device 1 shall exhibit.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities (e.g., the maximal blocking voltage) of the device 1.

As better illustrated in FIG. 10, the device 1 may further comprise a trench structure 14, 15, 16 that extends from the first side 110 into the semiconductor body 10 towards the second side 120, e.g., along the vertical direction Z.

The trench structure may comprise main control trenches 14, each of the main control trenches 14 including a main control trench electrode 141 electrically connected to a main control terminal 13-1 (cf. FIG. 1) and configured to control the forward load current under nominal conditions. Each main control trench 14 may include a main control trench insulator 142 that electrically insulates the main control trench electrode 141 from the semiconductor body 10.

The trench structure may further comprise auxiliary control trenches 15, each of the auxiliary control trenches 15 including an auxiliary control trench electrode 151 electrically connected with an auxiliary control terminal 13-2 and configured to control an overload current. Each auxiliary control trench 15 may include an auxiliary control trench insulator 152 that electrically insulates the auxiliary control trench electrode 151 from the semiconductor body 10.

The trench structure may further comprise source trenches 16, each of the source trenches 16 including a source trench electrode 161 electrically connected with the first load terminal 11. Each source trench 16 may include a source trench insulator 162 that electrically insulates the source trench electrode 161 from the semiconductor body 10.

As illustrated schematically in FIG. 2 and in more detail in FIG. 10, at the first side 110, the semiconductor body 10 may comprise a semiconductor body region 102 of the second conductivity type electrically connected to the first load terminal 11 and a semiconductor source region 101 of the first conductivity type electrically connected to the first load terminal 11, wherein the semiconductor source region 101 is isolated from the drift region 100 by at least the semiconductor body region 102.

The main control trench electrode 141 of the trench structure can be configured to induce, upon being subjected with a corresponding ON-control signal (e.g., provided by a driver unit) via a control terminal 13, an inversion channel in the semiconductor body region 102. This process may set the device 1 into the conducting state. The control trench electrode 141 can further be configured to cut off, upon being subjected with a corresponding OFF-control signal, the inversion channel in the semiconductor body region 102, which can set the device 1 into the forward biased blocking state.

The semiconductor source region 101 and the semiconductor body region 102 may be accommodated within mesas laterally confined by the main control trenches 14, the auxiliary control trenches 15 and the optionally provided source trenches 16. For example, first type mesas 17 are electrically connected to the first load terminal 11, e.g., via first contact plugs 111 penetrating an insulation layer 19, as illustrated in FIG. 10. The first type mesas 17 may be configured for conducting the forward load current. For example, second type mesas 18 are not connected to the first load terminal 11 in that manner.

It shall be understood that the source trenches 16 are optionally provided and that, based on the main control trenches 14, the auxiliary control trenches 15 and the optionally provided source trenches 16, arbitrary trench-mesa patterns may be formed in the active region 1-2, in accordance with some embodiments.

Referring to FIG. 2 again, a doped region 108 of the semiconductor body 10 below the drift region 100 adjoining the second load terminal 12 at the second side 120 can be configured in accordance with the designated characteristic of the device 1.

E.g., the doped region 108 can be an emitter region of the second conductivity type, if the device 1 shall exhibit an IGBT configuration. The doped region 108 is arranged in contact with the second load terminal 12. If the device 1 shall exhibit an RC IGBT configuration, the doped region 108 can be an emitter region of the second conductivity type exhibiting subsections of the first conductivity type, as it is known to the skilled person.

If the device 1 shall exhibit a MOSFET configuration, the doped region 108 can be a highly doped region of the first conductivity type adjoining the second load terminal 12.

In addition, a field stop region (not illustrated) of the first conductivity type can be provided between the drift region 100 and the second load terminal 12, wherein the field stop region exhibits a greater dopant concentration than the drift region 100.

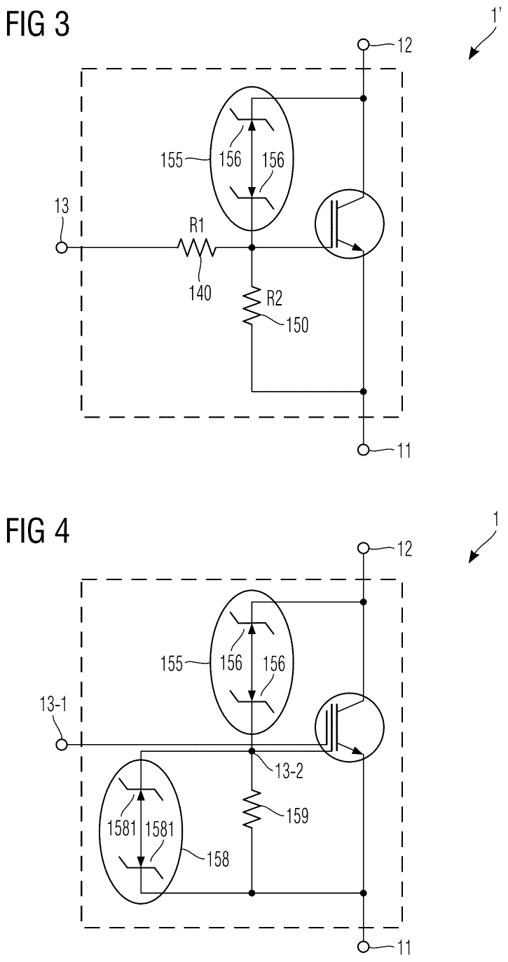

FIG. 3 schematically and exemplarily illustrates a circuit diagram of an exemplary power semiconductor device 1′. The device 1′ may for example exhibit a configuration as explained with respect to FIGS. 1, 2 and 10, without the auxiliary control trenches 15, though. There, an overload structure 155 is provided. For example, the overload structure 155 may include a plurality of Zener diodes 156 connected in series with each other. The overload structure 155 is connected to the second load terminal 12 and via resistor 140 (R1) to the control terminal 13. The overload structure 155 is further connected to the first load terminal 11 via resistor 150 (R2). For example, in an overload situation, during which, e.g., the voltage between the first load terminal 11 and the second load terminal 12 exceeds a maximal value, e.g., corresponding to the maximal blocking voltage of the device 1′, the overload structure 15 may become conductive and thereby, based on resistor 150 (R2), generate a voltage at the control terminal 13 that may set the device 1 into the forward conducting state (active voltage-clamping). A portion of the forward load current is then conducted by the device 1′ and another (usually by far smaller) portion thereof by the overload structure 155 and resistor 150 (R2).

FIG. 4 schematically and exemplarily illustrates a circuit diagram of the power semiconductor device 1 in accordance with an embodiment. The device 1 may for example exhibit a configuration as explained with respect to FIGS. 1, 2 and 10, now including the auxiliary control trenches 15, though.

Before further describing the embodiment illustrated in FIG. 4, it shall be understood that the present disclosure is not limited devices having a trench structure and/or a vertical configuration. For example, the herein explained technical teaching may likewise be applied to planar devices, where the electrodes 141, 151 and 161 are implemented as planar electrodes and where the semiconductor body 10 is configured to allow a lateral (instead of a vertical) forward load current. Irrespective of whether the electrodes 141, 151 and 161 are provided in a trench structure, the overload structure 155 may be provided and configured in accordance with the embodiments described below.

Reverting to FIG. 4, as illustrated, the device 1 comprises both a main control terminal 13-1 and an auxiliary control terminal 13-2. Each main control (trench) electrodes 141 is electrically connected to the main control terminal 13-1 and configured to control the forward load current under nominal conditions. Each of the auxiliary control (trench) electrodes 151 is electrically connected to the auxiliary control terminal 13-2 and configured to control the overload current. To this end, device 1 comprises the overload structure 155 connected between the second load terminal 12 and the auxiliary control terminal 13-2. The overload structure 155 is configured to apply an auxiliary control voltage greater than a threshold voltage to the auxiliary control (trench) electrodes 151, if a voltage between the first load terminal 11 and the second load terminal 12 exceeds a maximal value and/or if the voltage between the second load terminal 12 and the auxiliary control terminal 13-2 is above a breakthrough voltage of the overload structure 155.

The auxiliary control voltage is independent of the voltage applied at the main control terminal 13-1, in accordance with an embodiment. Further, the auxiliary control (trench) electrodes 151 may be electrically isolated from the main control (trench) electrodes 141.

The maximal value of the voltage between the first load terminal 11 and the second load terminal 12 may correspond to the maximal specified blocking voltage for which the device 1 has been designed. In an embodiment, the breakthrough voltage of the overload structure 155 is lower than the maximal blocking voltage of the power semiconductor device 1. For example, the maximal blocking voltage of the power semiconductor device 1 is in the range of 660 V to 720 V or, more general, 110% to 120% of the nominal voltage of the power semiconductor device 1. The breakthrough voltage of the overload structure 155 can be in the range of 660 V to 720 V. For example, the breakthrough voltage of the overload structure 155 is in the range of 100% to 110% of the maximal specified blocking voltage of the power semiconductor device 1.

The threshold voltage may be the minimum voltage necessary to induce a conductive channel in the semiconductor body 10 adjacent to the auxiliary control (trench) electrodes 151 for conduction of the overload current.

For example, the overload structure 155 is configured in a blocking state, if the voltage drop at the overload structure 155 is below the breakthrough voltage of the overload structure 155. This state may be present if the device 1 is operating under nominal conditions. The overload structure 155 can be configured in a conducting state, if the voltage drop at the overload structure 155 is above the breakthrough voltage. This state may be present if the device is not operating under nominal conditions, but is in an overload situation (active voltage-clamping).

Still referring to the circuit diagram of FIG. 4, in an embodiment, the device 1 further includes an ohmic structure 159 electrically connected between the first load terminal 11 and the auxiliary control terminal 13-2, wherein, for example, the ohmic structure exhibits a resistance of at least 200Ω, e.g., of around 500Ω. A portion of the voltage between the first load terminal 11 and the second load terminal 12 accordingly drops at both the ohmic structure 159 and the overload structure 155.

Due to the ohmic structure 159, during nominal operation of the device 1, the auxiliary control (trench) electrodes 151 exhibit the electrical potential of the first load terminal 11, in accordance with an embodiment. Thus, during nominal operation, i.e., when there is no overload situation, the auxiliary control (trench) electrodes 151 may act similar as the optionally provided source (trench) electrodes 161.

Furthermore, based on of the resistance of the ohmic structure 159, the amount of current in the overload structure 155 may be limited, e.g., to the maximum capabilities of its Zener diodes 156 described below.

Here, it is noted that in contrast to the group of the first load terminal 11, the second load terminal 12 and the main control terminal 13-1, the auxiliary control terminal 13-2 may but must not necessarily be connectable to external means. As will be explained in more detail below, the auxiliary control voltage applied to the auxiliary control (trench) electrodes 151 may be generated device internally. The control signal for the main control (trench) electrodes 141 is generated device externally, e.g., by a driver unit applying a voltage between the first load terminal 11 and the main control terminal 13, in accordance with an embodiment. For example, the auxiliary control voltage is independent from the voltage applied at the main control terminal 13-1.

In an embodiment, as illustrated exemplarily in FIG. 4, the overload structure 155 comprises Zener diodes 156 connected in series with each other. For example, the breakthrough voltage corresponds with the sum of the Zener voltages of the Zener diodes 156. For example, as indicated in FIG. 4, the Zener diodes 156 are connected in series with each other with changing polarity, e.g., such that the breakthrough voltage corresponds to the sum of the Zener voltages of half of the Zener diodes 156 and the forward voltages of the other half of the Zener diodes.

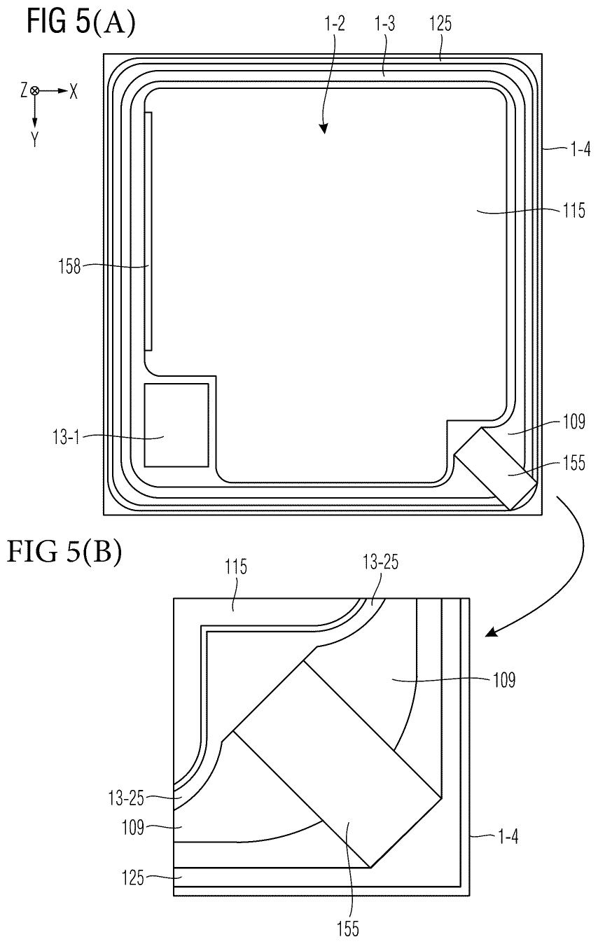

In accordance with an embodiment (cf. also FIGS. 5A and 5B), the overload structure 155 is arranged at the first side 110, e.g., to define a laterally extending path between the potential of the auxiliary control terminal 13-2 (e.g., provided by the auxiliary control terminal contact 13-21) and the potential of the second load terminal 12 (e.g., provided by the load terminal contact 121). Furthermore, in accordance with an embodiment, the overload structure 155 is arranged in the edge termination region 1-3. For example, the overload structure 155 does not extend into the active region 1-2. Furthermore, in accordance with an embodiment, the overload structure 155 may laterally overlap, e.g., in the edge termination region 1-3, with a variation-of-the-lateral-doping-, VLD, region of the semiconductor body 10, as will be explained further below in more detail.

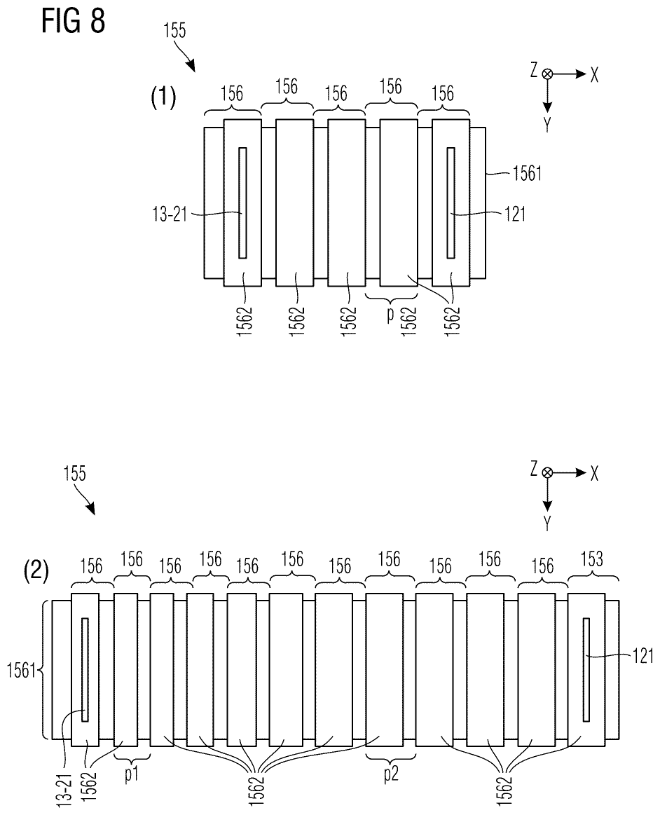

Two variants of a configuration of the overload structure 155 are exemplarily illustrated in FIG. 8. For example, the series connection of the Zener diodes 156 is implemented in a portion of the semiconductor body 10. Each Zener diode 156 may include a first semiconductor region 1561 of the first conductivity type and, in contact therewith, a second semiconductor region 1562 of the second conductivity type. For example, the Zener diodes 156 are connected in series with each other with changing polarity in that adjacent second semiconductor region 1562 share one of first semiconductor region 1561, as illustrated in FIG. 8. To establish the electrical connection between the overload structure 155 and the second load terminal 12, a load terminal contact 121 may be employed, e.g., coupled to one of the second semiconductor regions 1562 starting the series connection of the Zener diodes 156. To establish the electrical connection between the overload structure 155 and the auxiliary control terminal 13-2, an auxiliary control terminal contact 13-21 may be employed, e.g., coupled to another one of the second semiconductor regions 1562 terminating the series connection of the Zener diodes 156.

In accordance with variant (1) illustrated in FIG. 8, the pitch p of each of the Zener diodes 156 may be constant along the (e.g., lateral) extension of the overload structure 155.

In accordance with variant (2) illustrated in FIG. 8, the pitch the Zener diodes 156 may vary, e.g., along the lateral extension of the overload structure 155. For example, the Zener diodes 156 closer to the load terminal contact 121 are configured with a greater pitch p2, whereas Zener diodes closer to the auxiliary control terminal contact 13-21 are configured with a smaller pitch p1. In another non-illustrated embodiment, Zener diodes 156 closer to the load terminal contact 121 can be configured with a smaller pitch, whereas Zener diodes closer to the auxiliary control terminal contact 13-21 are configured with a greater pitch.

For example, the pitch of the series connection of Zener diodes (diode chain) 156 changes according to the electrical field strength in the edge termination region 1-3. Accordingly, the same or at least similar field distribution in the edge termination region 1-3 and the overload structure 155 in the device blocking state can be achieved. At regions with higher field strengths in the edge termination region 1-3, the pitch can be smaller (pitch p1), whereas in regions with smaller field strengths, the pitch can be greater (pitch p2). To achieve the varying pitches, the lateral extensions of the first semiconductor regions 1561 and/or the second semiconductor regions 1562 may be varied, e.g., based on corresponding masked implantation.

Furthermore, in accordance with an embodiment, resistor 140 (R1) mentioned with respect to FIG. 3 can be omitted for the power semiconductor device 1. Rather, the connection between the main control terminal 13-1 and the main control trench electrodes 141 can be a low ohmic connection, e.g., with a resistance of less than 100Ω or of even less than 20Ω.

As indicated above and still referring to FIG. 4, the power semiconductor device 1 can be a transistor, such as a MOSFET or an IGBT, and can be configured to be operated at a switching frequency of at least 5 kHz or of even more than 30 kHz. For example, such configuration for a high switching frequency of at least 10 kHz includes the low ohmic connection between the main control terminal 13-1 and the main control trench electrodes 141 of less than 100Ω. Furthermore, based on the overload structure 155 and the auxiliary control (trench) electrodes 151, the device 1 can be configured as a voltage self-clamping device, e.g., as an active voltage self-clamping device.

Furthermore, in accordance with an embodiment, the active region 1-2 comprises a plurality of power unit cells, wherein each power unit cell comprises at least one of the main control trenches 14 and at least one of the auxiliary control trenches 15. This optional aspect will be described in greater detail below with respect to the remaining drawings.

Still referring to FIG. 4, in accordance with an embodiment, the power semiconductor device 1 further comprises a gate emitter clamping structure 158 coupled between the auxiliary control terminal 13-2 and the first load terminal 11. For example, the gate emitter clamping structure 158 includes a plurality of Zener diodes 1581 connected in series with each other. For example, as indicated in FIG. 4, the Zener diodes 1581 of the gate emitter clamping structure 158 are connected in series with each other with changing polarity. The gate emitter clamping structure 158 is optional and not necessary for the function of the overload structure 155.

In another embodiment, instead of the Zener diodes 156, the overload structure 155 can comprise an auxiliary transistor and/or one or more other structural elements configured to apply the auxiliary control voltage greater than a threshold voltage to the auxiliary control trench electrodes 151, if the voltage between the first load terminal 11 and the second load terminal 12 exceeds a maximal value and/or if the voltage between the second load terminal 12 and the auxiliary control terminal 13-2 is above a breakthrough voltage of the overload structure 155. That is, the term “breakthrough voltage” does not necessarily imply that the overload structure 155 has a breakthrough configuration.

FIG. 5(A) illustrates schematically and exemplarily a horizontal projection of the power semiconductor device 1, and FIG. 5(B) a more detailed view of the lower right corner with a modification regarding the connection of the overload structure 155.

Illustrated in FIG. 5(A) is the chip edge 1-4, the edge termination region 1-3 and the active region 1-2. For example, based on a first front side metallization 115 in the active region 1-2, an electrical connection between the first contact plugs 111 (cf. FIG. 10) and the first load terminal 11 is established. Based on a second front side metallization 125 in the edge termination region 1-3, the potential of the second load terminal 12 is made available at the front side 110. For example, based on the second front side metallization 125, an electrical connection between the load terminal contact 121 (cf. FIG. 8), i.e., the overload structure 155, and the second load terminal 12 is established.

In accordance with an embodiment, cf. FIG. 5(B), a third front side metallization 13-25 is employed for establishing the electrical connection between the auxiliary control terminal contact 13-21 (cf. also FIG. 8), the auxiliary control (trench) electrodes 151 and the overload structure 155.

As illustrated in FIGS. 5(A) and 5(B), the overload structure 155 may be arranged in the edge termination region 1-3, e.g., in a corner region thereof. Further, the overload structure 155 may laterally overlap with the above-mentioned variation-of-the-lateral-doping-, VLD, region 109 of the semiconductor body 10. For example, the VLD region 109 is of the second conductivity type. Furthermore, the VLD region 109 may be electrically connected with the potential of the first load terminal 11.

As also illustrated in FIG. 5(A), the main control terminal 13-1 may also be arranged at the front side of the device 1, e.g., in another corner region. In contrast to the illustration in FIG. 5(A), the main control terminal 13-1 could also be arranged in the upper left corner, e.g., diagonally opposite to the overload structure 155. Also the optionally provided gate emitter clamping structure 158 may be arranged in the edge termination region 1-3.

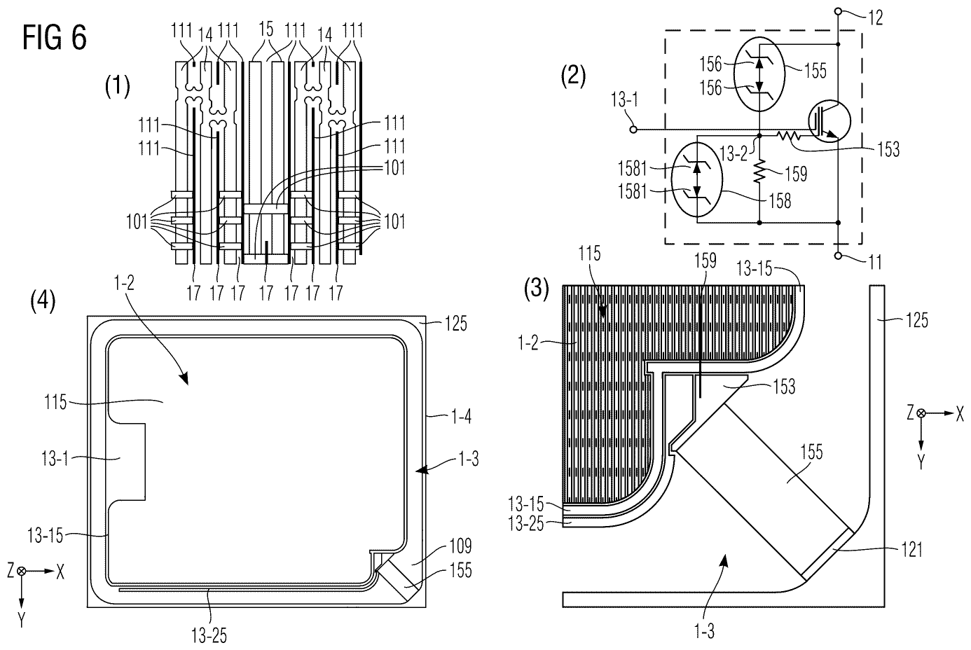

FIG. 6 schematically and exemplarily illustrates four views (1) to (4) of a further embodiment of the power semiconductor device 1. In this embodiment, the power semiconductor device 1 further comprises a damping resistor 153 (cf. view (2)) between the auxiliary control terminal 13-2 and the auxiliary control (trench) electrodes 151. For example, the resistance of the damping resistor 153 is within the range of 10Ω to 100Ω. Apart from the damping resistor 153, view (2) corresponds to FIG. 4 and the associated description likewise applies there. Views (4) and (3) essentially correspond to FIGS. 3(A) and 3(B) and the associated description likewise applies there.

Views (1) and (3) of FIG. 6 schematically illustrated an exemplarily trench-mesa-pattern that may be implemented in the active region 1-2. For example, cf. view (1), each power unit cell comprises three main control trenches 14 and two auxiliary control trenches 15. The three main control trenches 14 may be connected with each other based on small cross-trench units bridging the two first type mesas 17 that are laterally confined by the three control trenches, as illustrated. The first contact plugs 111 are employed to establish the electrical connection between the first type mesas 17 and the first load terminal 11, as already described with respect to FIG. 10. Each of the first type mesas 17 is arranged laterally adjacent to at least one of the main control trenches 14 and/or to at least one of the auxiliary control trenches 15.

Also illustrated in FIG. 6, view (1), are the source regions 101 in the first type mesas 17. Based on the source regions 101 in the first type mesas 17, a channel width in the respective first type mesa may be configured.

In accordance with an embodiment, a first channel width present within the first type trenches 17 not laterally adjacent to at least one of the auxiliary control trenches 15 is different from a second channel width present in the first type mesas 17 laterally adjacent to at least one of the auxiliary control trenches 15. For example, as illustrated in FIG. 6, view (1), the second channel width is greater than the first channel width. For example, more source regions 101 are provided in the first type mesas 17 that are laterally confined by at least one of the auxiliary control trenches 15 as compared to the first type mesas 17 that are not laterally confined by at least one of the auxiliary control trenches 15.

Referring to views (2) and (3) of FIG. 6, the ohmic structure 159 electrically connected between the first load terminal 11 and the auxiliary control terminal 13-2 may be formed by one or more prolonged trenches, depending on the designator resistance of the ohmic structure 159.

A fourth frontside metallization 13-15, e.g., having a runner configuration, partially surrounds the active region 1-2 to provide the electrical potential of the main control terminal 13-1 for each of the main control trenches 14. Also the third front side metallization 13-25 may exhibit a runner configuration.

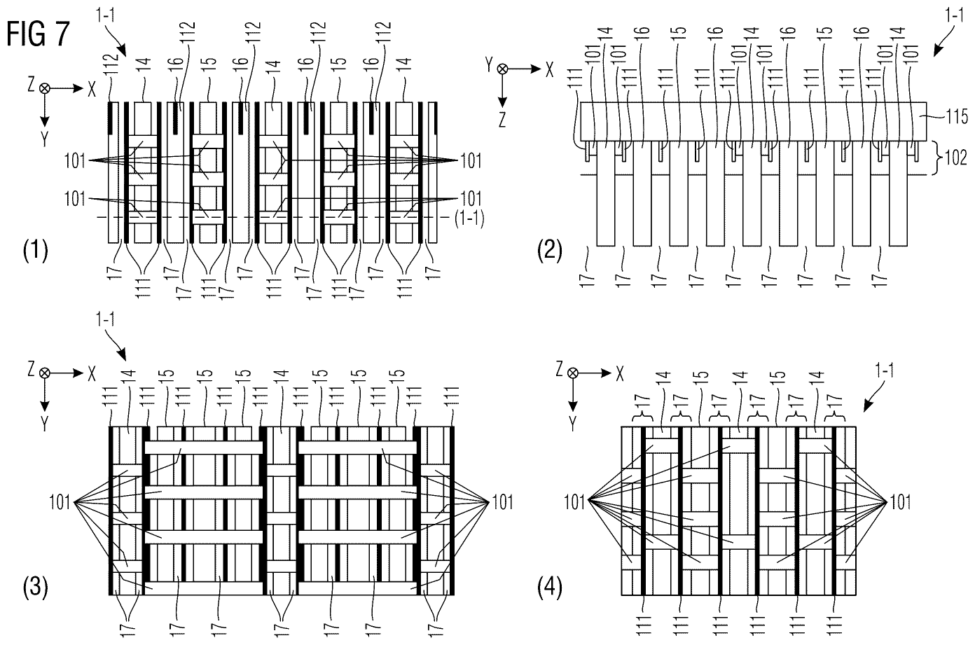

Aspects of further embodiments of the power semiconductor device 1 are schematically illustrated based on the four views (1) to (4) of FIG. 7.

For example, view (1) illustrates another trench-mesa pattern that may be implemented in the active region 1-2. There, each power unit cell may include one main control trench 14, two source trenches 16 and one auxiliary control trench 15 arranged between the two source trenches 16. Second contact plugs 112 may be employed to electrically connect the source trench electrodes 161 (cf. FIG. 10) with the potential of the first load terminal 11. View (2) of FIG. 7 illustrates a section of a vertical cross-section along line 1-1 indicated in view (1).

View (3) of FIG. 7 illustrates another trench-mesa pattern that may be implemented in the active region 1-2. There, no separate source trenches 16 are provided. Rather, each power unit cell includes one main control trench 14 and three auxiliary control trenches 15. As has been described above, when the device 1 is operating under nominal conditions (i.e., no overload situation), the electrical potential of the auxiliary control trench electrodes 151 is substantially the same as the potential of the first load terminal 11; i.e., under nominal conditions, the auxiliary control trenches 15 may act as source trenches 16. As has also been explained above, the channel width in the first type mesas 17 that are laterally confined by at least one of the auxiliary control trenches 15 may vary from first type mesas 17 that are laterally confined by only one or more of the main control trenches 14 and/or by one or more of the source trenches 16 (if provided). In accordance with an embodiment, the source regions 101 at the main control trenches 14 are provided with a first pitch, and the source regions 101 at the auxiliary control trenches 15 are provided with a second pitch. For example, the first pitch (e.g., along the second lateral direction Y) is the same as the second pitch (e.g., along the second lateral direction Y). In another embodiment, the second pitch is different from the first pitch.

View (4) of FIG. 7 illustrates another trench-mesa pattern that may be implemented in the active region 1-2. Again, no separate source trenches 16 are provided. Rather, each power unit cell includes one main control trench 14 and one auxiliary control trenches 15.

As apparent from the above description, the auxiliary control trenches 15 can be easily integrated in diverse trench-mesa patterns.

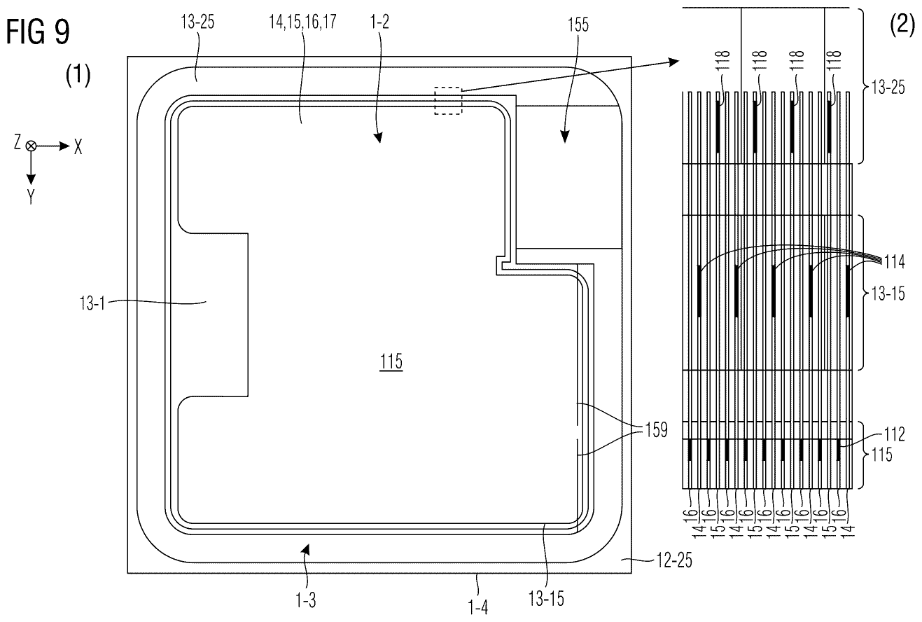

According to the trench-mesa-pattern illustrated by views (1) and (2) of FIG. 9 (wherein (2) illustrates a close-up of the region indicated by the dashed lines in view (1)), each main control trench 14 is arranged between two source trenches 16, and each auxiliary control trench 15 is also arranged between two source trenches 16. As explained above, both the third front side metallization 13-25 (used to establish the electrical connection between the overload structure 155 and the auxiliary control trench electrodes 151) and the fourth front side metallization 13-15 (used to establish the electrical connection between the main control terminal 13-1 and the main control trench electrodes 141) may exhibit a runner configuration at least partially surrounding the active region 1-2. For example, similar to the second contact plugs 112 employed to connect the source trench electrodes 161 with the first front side metallization 115 (i.e., with the first load terminal 11), fourth contact plugs 114 may be employed to electrically connect the main control trench electrodes 141 with the fourth front side metallization 13-15 (i.e., with the main control terminal 13-1), and third contact plugs 118 may be employed to electrically connect the auxiliary control trench electrodes 151 with the third front side metallization 13-25 (i.e., with the overload structure 155). To ensure a reliable connection, each auxiliary control trench electrode 151 may be connected to the third front side metallization 13-25 (i.e., with the overload structure 155) based on at least two separately arranged third contact plugs 118. To this end, the third front side metallization 13-25 may extend along both the upper portion of the edge termination region 1-3 indicated in view (1) and the lower portion of the edge termination region 1-3. Alternatively or additionally, other contacting schemes may be employed, e.g., small cross-trench elements as explained with respect to FIG. 6, view (1), for the main control trenches 14.

Still referring to FIG. 9, as described above, the ohmic structure 159 electrically connected between the first load terminal 11 and the auxiliary control terminal 13-2 may be formed by one or more (e.g., two, as illustrated) prolonged trenches, depending on the designator resistance of the ohmic structure 159. For example, the ohmic structure 159 can be integrated by use of source trenches 16 without source regions 101 at the edge of the active area 1-2, e.g. at the area/lines shown in view (1) of FIG. 9 indicated with reference numeral 159. One end of the trench(es) employed for forming the ohmic structure 159 can be contacted to third front side metallization 13-25, and the other end to the first front side metallization 115.

In accordance with the embodiment of FIG. 9, the overload structure 155 is arranged in the upper right-hand corner of the power semiconductor device 1. There, the overload structure 155 is contacted by a metal ring 12-25 on the one side and by the third front side metallization 13-25 (configured as a metal ring) on the other side. For example, each of the auxiliary control electrodes 151 is connected to the third front side metallization 13-25 (configured as a metal ring) based on two of the third contact plugs 118, e.g., by one third contact plug 118 in an area corresponding to an upper portion of FIG. 9 and by another third contact plug 118 in an area corresponding to a lower portion of FIG. 9 (wherein the trenches 14, 15 extend along the second lateral direction from the upper portion to the lower portion). Alternatively or additionally, such redundancy can also be reached by one or more (non-illustrated) cross trenches at one of the ends of the auxiliary control trenches 15. Then, the third front side metallization 13-25 (metal runner) is only needed on one side of the chip, e.g., in either the upper or the lower portion.

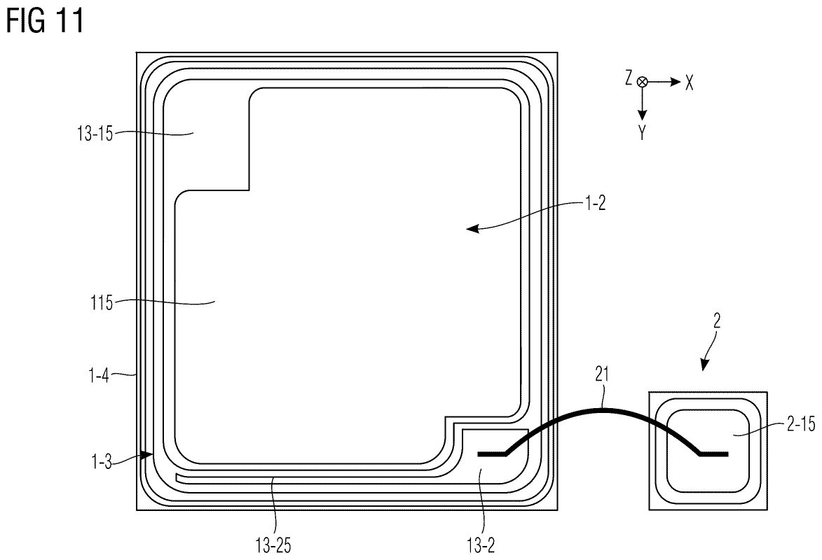

In accordance with a further embodiment illustrated in FIG. 11, the overload structure 155 is omitted in the power semiconductor device 1 and the auxiliary control terminal 13-2 is provided at the front side of the power semiconductor device 1. The auxiliary control terminal 13-2 is coupled to a terminal 2-15 of an external clamping chip 2, e.g., via a bond wire 21.

The external clamping chip 2 may exhibit a diode configuration, e.g., an avalanche diode configuration, e.g., with an avalanche voltage below the avalanche voltage of the power semiconductor device 1. Both the power semiconductor device 1 and the external clamping chip 2 may be integrated within the same package. The external clamping chip 2 may be controlled based on the voltage at the auxiliary control terminal 13-2.

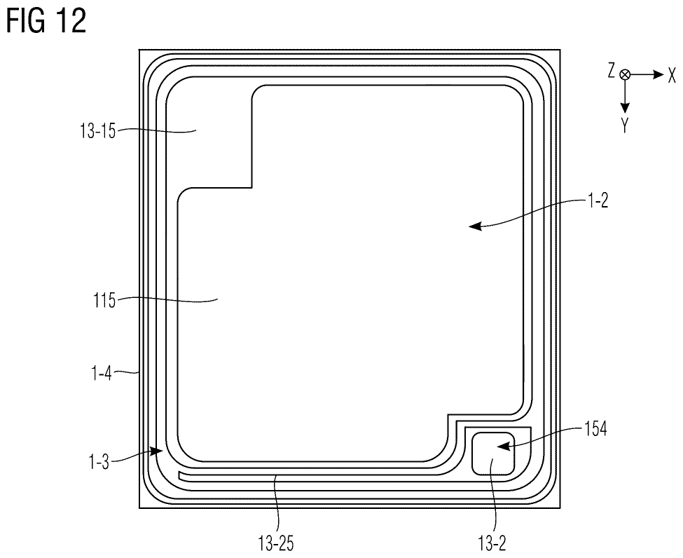

The embodiment illustrated in FIG. 12 corresponds to the embodiment of FIG. 11, wherein there is neither an external chip 2 provided nor the overload structure 155 in the power semiconductor device 1. Rather, below the auxiliary control terminal 12, i.e., within the edge termination region 1-3 and as part of the semiconductor body 10, an avalanche structure 154 is provided configured to conduct at least a portion of the load current in an overload situation. For example, the avalanche structure 154 comprises a deep semiconductor region of the second conductivity type and/or is implemented in a trench structure within the edge termination region 1-3.

Presented herein is also a method of producing a power semiconductor device.

For example, the method of producing a power semiconductor device comprises forming the following components: an active region surrounded by an edge termination region; a semiconductor body extending in both the active region and the edge termination region and comprising, in the active region a semiconductor drift region of a first conductivity type; a first load terminal at a first side of the semiconductor body; a second load terminal at a second side of the semiconductor body opposite to the first side, wherein the power semiconductor device is configured to conduct, in the active region a forward load current between the first load terminal and the second load terminal; a main control terminal; an auxiliary control terminal isolated from the main control terminal; in the active region, a trench structure extending along a vertical direction from the first side towards the second side, wherein the trench structure comprises main control trenches, each of the main control trenches including a main control trench electrode electrically connected to the main control terminal and configured to control the forward load current, and auxiliary control trenches, each of the auxiliary control trenches including an auxiliary control trench electrode electrically connected to the auxiliary control terminal and configured to control an overload current; an overload structure connected between the second load terminal and the auxiliary control terminal, wherein the overload structure is configured to apply an auxiliary control voltage greater than a threshold voltage to the auxiliary control trench electrodes, if a voltage between the first load terminal and the second load terminal exceeds a maximal value and/or if the voltage between the second load terminal and the auxiliary control terminal is above a breakthrough voltage of the overload structure.

In another example, the method of producing a power semiconductor device comprises forming the following components: a semiconductor body; a first load terminal; a second load terminal, wherein the power semiconductor device is configured to conduct a forward load current between the first load terminal and the second load terminal; a main control terminal; an auxiliary control terminal isolated from the main control terminal; a control electrode structure comprising: main control electrodes electrically connected to the main control terminal and configured to control the forward load current, and auxiliary control electrodes electrically connected to the auxiliary control terminal and configured to control an overload current; an overload structure electrically connected between the second load terminal and the auxiliary control terminal, wherein the overload structure is configured to apply an auxiliary control voltage greater than a threshold voltage to the auxiliary control electrodes, if a voltage between the first load terminal and the second load terminal exceeds a maximal value and/or if the voltage between the second load terminal and the auxiliary control terminal is above a breakthrough voltage of the overload structure.

Embodiments of the above-described methods correspond to the embodiments of the power semiconductor device 1 described above. Accordingly, these embodiments of the method will not literally be described herein, but it is referred to the above.

For example, for forming the overload structure 155 (e.g. as illustrated in and described with respect to FIGS. 4 to 9), a deposited, e.g., ˜500 nm thick, undoped polysilicon is first weakly e.g. n-doped. Then based on a masked e.g. p-doping, a diode chain of the above described series connection of Zener diodes 156 may be formed. The non-needed polysilicon can be etched off.

For example, for forming the overload structure 155 (e.g. as illustrated in and described with respect to Figs. x) by introducing a region with reduced avalanche voltage by e.g. a deep well area of the second conductivity type in the power semiconductor device 1. This deep well can be integrated in combination with a trench bottom implant.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

What is claimed is:

1. A power semiconductor device, comprising:
an active region surrounded by an edge termination region;
a semiconductor body extending in both the active region and the edge termination region and comprising, in the active region, a semiconductor drift region of a first conductivity type;
a first load terminal at a first side of the semiconductor body;
a second load terminal at a second side of the semiconductor body opposite to the first side, wherein the power semiconductor device is configured to conduct, in the active region, a forward load current between the first load terminal and the second load terminal;
a main control terminal;
an auxiliary control terminal isolated from the main control terminal;
in the active region, a trench structure extending along a vertical direction from the first side towards the second side, wherein the trench structure comprises:
a plurality of main control trenches each including a main control trench electrode electrically connected to the main control terminal and configured to control the forward load current; and
a plurality of auxiliary control trenches each including an auxiliary control trench electrode electrically connected to the auxiliary control terminal) and configured to control an overload current;
an overload structure connected between the second load terminal and the auxiliary control terminal, wherein the overload structure is configured to apply an auxiliary control voltage greater than a threshold voltage to the auxiliary control trench electrodes, if a voltage between the first load terminal and the second load terminal exceeds a maximal value and/or if the voltage between the second load terminal and the auxiliary control terminal is above a breakthrough voltage of the overload structure.

2. The power semiconductor device of claim 1, wherein the overload structure is configured:
in a blocking state, if the voltage drop at the overload structure is below the breakthrough voltage of the overload structure; and
in a conducting state, if the voltage drop at the overload structure is above the breakthrough voltage.

3. The power semiconductor device of claim 1, further comprising an ohmic structure electrically connected between the first load terminal and the auxiliary control terminal, wherein the ohmic structure has a resistance of at least 200 Ω.

4. The power semiconductor device of claim 1, wherein the overload structure comprises Zener diodes connected in series with each other, and wherein the breakthrough voltage corresponds with a sum of the Zener voltages of the Zener diodes.

5. The power semiconductor device of claim 4, wherein a pitch in the series connection of the Zener diodes varies.

6. The power semiconductor device of claim 1, wherein the overload structure is arranged at the first side to define a laterally extending path between a potential of the auxiliary control terminal and a potential of the second load terminal.

7. The power semiconductor device of claim 1, wherein the overload structure is arranged in the edge termination region.

8. The power semiconductor device of claim 1, wherein the overload structure laterally overlaps with a variation-of-the-lateral-doping region of the semiconductor body.

9. The power semiconductor device of claim 1, wherein the connection between the main control terminal and the main control trench electrodes is a low ohmic connection with a resistance of less than 100 Ω.

10. The power semiconductor device of claim 1, wherein the power semiconductor device is a transistor configured to be operated at a switching frequency of at least 5 kHz.

11. The power semiconductor device of claim 1, wherein the active region comprises a plurality of power unit cells, and wherein each power unit cell comprises at least one of the main control trenches and at least one of the auxiliary control trenches.

12. The power semiconductor device of claim 1, wherein the trench structure further comprises a plurality of source trenches each including a source trench electrode electrically connected to the first load terminal.

13. The power semiconductor device of claim 1, wherein the power semiconductor device is a voltage self-clamping device.

14. The power semiconductor device of claim 1, further comprising a damping resistor between the auxiliary control terminal and the auxiliary control trench electrodes.

15. The power semiconductor device of claim 1, wherein the trench structure laterally confines a plurality of first type mesas each arranged laterally adjacent to at least one of the main control trenches and/or to at least one of the auxiliary control trenches.

16. The power semiconductor device of claim 15, wherein a first channel width present within the first type mesas not laterally adjacent to at least one of the auxiliary control trenches is different from a second channel width present in the first type mesas laterally adjacent to at least one of the auxiliary control trenches.

17. The power semiconductor device of claim 1, wherein the breakthrough voltage of the overload structure is lower than a maximal blocking voltage of the power semiconductor device.

18. The power semiconductor device of claim 1, wherein the auxiliary control trench electrodes exhibit, during nominal operation of the power semiconductor device, an electrical potential of the first load terminal.

19. A power semiconductor device, comprising:
a semiconductor body;
a first load terminal;
a second load terminal, wherein the power semiconductor device is configured to conduct a forward load current between the first load terminal and the second load terminal;
a main control terminal;
an auxiliary control terminal isolated from the main control terminal;
a control electrode structure comprising:
a plurality of main control electrodes electrically connected to the main control terminal and configured to control the forward load current; and
a plurality of auxiliary control electrodes electrically connected to the auxiliary control terminal and configured to control an overload current;
an overload structure electrically connected between the second load terminal and the auxiliary control terminal, wherein the overload structure is configured to apply an auxiliary control voltage greater than a threshold voltage to the auxiliary control electrodes, if a voltage between the first load terminal and the second load terminal exceeds a maximal value and/or if a voltage between the second load terminal and the auxiliary control terminal is above a breakthrough voltage of the overload structure.

20. A method of producing a power semiconductor device, the method comprising:
forming an active region surrounded by an edge termination region, with a semiconductor body extending in both the active region and the edge termination region and comprising, in the active region, a semiconductor drift region of a first conductivity type;
forming a first load terminal at a first side of the semiconductor body;
forming a second load terminal at a second side of the semiconductor body opposite to the first side, wherein the power semiconductor device is configured to conduct, in the active region, a forward load current between the first load terminal and the second load terminal;
forming a main control terminal;
forming an auxiliary control terminal isolated from the main control terminal;
in the active region, forming a trench structure extending along a vertical direction from the first side towards the second side, wherein the trench structure comprises:
a plurality of main control trenches each including a main control trench electrode electrically connected to the main control terminal and configured to control the forward load current; and
a plurality of auxiliary control trenches each including an auxiliary control trench electrode electrically connected to the auxiliary control terminal) and configured to control an overload current;
forming an overload structure connected between the second load terminal and the auxiliary control terminal, wherein the overload structure is configured to apply an auxiliary control voltage greater than a threshold voltage to the auxiliary control trench electrodes, if a voltage between the first load terminal and the second load terminal exceeds a maximal value and/or if the voltage between the second load terminal and the auxiliary control terminal is above a breakthrough voltage of the overload structure.
